(19) United States
(12) Patent Application Publication
(10) Pub. No.: US 2008/0037332 A1
(43) Pub. Date: Feb. 14, 2008

(54) SEMICONDUCTOR STORAGE DEVICE AND ELECTRONIC EQUIPMENT

(76) Inventor: Yoshiji OHTA, Osaka (JP)

Correspondence Address: BIRCH STEWART KOLASCH & BIRCH, PO BOX 747, FALLS CHURCH, VA, 22040-0747, US

(21) Appl. No.: 11/836,632

(22) Filed: Aug. 9, 2007

(30) Foreign Application Priority Data
Aug. 9, 2006 (JP) 2006-216704

(51) Int. Cl. G11C 16/00

(52) U.S. Cl. 365/185.23

(57) ABSTRACT

A semiconductor storage device is capable of discriminating information stored in memory cells with high accuracy even if a gap that separates distributions of cell current values between data 0 and data 1 among a plurality of memory cells in a memory cell array becomes extremely narrow or overlapped with each other. A first memory cell MC11 and a second memory cell MC2 are adjacent to each other, and a first bit line BL1 to which a first input/output terminal of the first memory cell MC11 is connected as well as a second bit line BL2 to which a second input/output terminal of the second memory cell MC12 is connected are connected to inputs of a sense amplifier SA1, respectively. A second input/output terminal of the first memory cell MC11 and a first input/output terminal of the second memory cell MC12 are connected to a common line COM.

This nonprovisional application claims priority under 35 U.S.C. §119(a) on Patent Application No. 2006-216704 filed in Japan on Aug. 9, 2006, the entire contents of which are hereby incorporated by reference.

### BACKGROUND OF THE INVENTION

The present invention relates to semiconductor storage devices and, more particularly, to a semiconductor storage device including nonvolatile memory cells, such as flash memory cells or mask ROM (Read Only Memory) cells, having a function of storing data in the vicinity of one end or both ends of one channel region independently of one another. The invention also relates to electronic equipment having the semiconductor storage device.

In recent years, nonvolatile semiconductor storage devices such as flash memory, ferroelectric memory or mask ROM have been widely used as semiconductor storage elements for use of data storage of portable telephones or digital cameras or for use of code (program) storage.

Such nonvolatile memory cells, which are for determining information by using changes in cell currents (currents flowing through memory cells) corresponding to storage states, have a structural difficulty in making cell currents completely coincident among a plurality of memory cells in which identical information has been stored. Therefore, it is usually the case that among a plurality of memory cells, even if identical information is stored therein, their cell current values are distributed to some degree of width. However, if the distributions of the cell current values overlap among memory cells in which different information has been stored, correct information determination would no longer be achieved. For this reason, for memory cells in which different information is stored, program verify operations are applied for adjustment so that their cell current distributions do not overlap thereamong, i.e., there occur gaps among their distributions. Unfortunately, the gaps by which their cell current distributions are separated from each other have recently been going narrower together with advancing further scale-down, lower-going voltages and the like, as a problem. In addition, on a plurality of memory cells, there are influences in degrees varying from memory cell to memory cell by disturb (external disturb due to accesses to other memory cells), endurance (deteriorations in rewrite characteristics of memory cells due to increases in the number of rewrite operations), retention (holding characteristics for stored information due to temperature variations, time changes, etc.), and the like. From these and other reasons, the distributions of cell current value of individual memory cells become larger stretched, resulting in a problem that the gap that separates distributions of cell current values between data 0 and data 1 becomes extremely narrow or overlapped with each other so as to make it impossible to discriminate data 0 and data 1 from each other.

As a typical technique for conventional read operations, there has been a semiconductor storage device in which with a reference cell or reference cells provided, its current value or their average current value, taken as a reference current value, is compared with a cell current value of a memory cell to be read, by which information determination is implemented (see JP 2004-273093 A). More specifically, data 0 and data 1 are preparatorily stored in two reference, and their average current value is used as a reference current value.

However, with this conventional semiconductor storage device, it would be impossible to correctly read information stored in memory cells when distributions of data 0 and data 1 have an extremely narrow gap therebetween or overlap with each other (i.e., have no gap therebetween).

### SUMMARY OF THE INVENTION

Accordingly, an object of the present invention is to provide a semiconductor storage device capable of discriminating information stored in memory cells with high accuracy even with occurrence of extremely narrow gaps between cell current value distributions between data 0 and data 1 among a plurality of memory cells in a memory cell array, or with occurrence of overlaps between those distributions.

In order to achieve the above object, according to the present invention, there is provided a semiconductor storage device comprising:

first and second memory cells each having an information-storable storage area in the vicinity of a channel region or in the vicinity of one end of the channel region, and having a first input/output terminal on one end side of the channel region and a second input/output terminal on the other end side of the channel region;

a first bit line to which the first input/output terminal of the first memory cell is connected;

a second bit line to which the second input/output terminal of the second memory cell is connected;

a common line to which the second input/output terminal of the first memory cell and the first input/output terminal of the second memory cell are connected;

a word line to which control gates of the first memory cell and the second memory cell are connected;

a first bit line driver to an output of which the first bit line is connected;

a second bit line driver to an output of which the second bit line is connected;

a common line driver to an output of which the common line is connected; and

a sense amplifier to inputs of which the first and second bit lines are connected, respectively.

According to the above structure, the first bit line to which the first input/output terminal of the first memory cell is connected, and the second bit line to which the second input/output terminal of the second memory cell is connected are connected to the inputs of the sense amplifier, respectively, and moreover the second input/output terminal of the first memory cell and the first input/output terminal of the second memory cell are connected to the common line. Thus, through discharge from the common line to the first and second bit lines, or through charge from the first and second bit lines to the common line, the sense amplifier can fulfill read operation by utilizing status differences of the first and second memory cells.

Therefore, according to the present invention, information stored in the memory cells can correctly be read out without using any reference voltage or reference cell.

According to an aspect of the present invention, there is provided a semiconductor storage device comprising:

first and second memory cells each having an information-storable storage area in the vicinity of a channel region or in the vicinity of one end of the channel region, and having a first input/output terminal on one end side of the channel region and a second input/output terminal on the other end side of the channel region;

a first local bit line to which the first input/output terminal of the first memory cell is connected;

a second local bit line to which the second input/output terminal of the second memory cell is connected;

a third local bit line to which the second input/output terminal of the first memory cell and the first input/output terminal of the second memory cell are connected;

first to third switching elements to one-side ends of which the first to third local bit lines are connected, respectively;

a first global bit line to which the other end of the first switching element is connected;

a second global bit line to which the other end of the second switching element is connected;

a common line to which the other end of the third switching element is connected;

a word line to which control gates of the first memory cell and the second memory cell are connected;

a first bit line driver to an output of which the first global bit line is connected;

a second bit line driver to an output of which the second global bit line is connected;

a common line driver to an output of which the common line is connected; and

a sense amplifier to inputs of which the first and second global bit lines are connected, respectively.

In this semiconductor storage device, the first to third local bit lines are connected to one-side ends of the first to third switching elements, respectively, and first global bit line to which the other end of the first switching element is connected as well as the second global bit line to which the other end of the second switching element is connected are connected to the inputs of the sense amplifier, respectively. Therefore, the number of memory cells that can be read out by one sense amplifier can be increased without impairing the reading accuracy.

In one embodiment, one set of the first memory cell and the second memory cell, and another set of the first memory cell and the second memory cell adjacent to the one set, share one sense amplifier.

In this embodiment, since one sense amplifier is shared between a plurality of sets of adjacent memory cells, a larger number of memory cells can be read out with a smaller number of sense amplifiers without impairing the reading accuracy.

In addition, the direction in which the sets of memory cells are adjacent to one another is desirably a direction along the word line direction or the bit line direction.

In one embodiment, the storage area of the first memory cell is set to an erase state while the storage area of the second memory cell is set to a write state so that data 0 or data 1 is stored, and, conversely, the storage area of the first memory cell is set to a write state while the storage area of the second memory cell is set to an erase state so that data 1 or data 0 is stored.

In this embodiment, since the read operation is fulfilled by utilizing status differences of the first and second memory cells, information stored in the memory cells can correctly be read out without using any reference voltage or reference cell.

According to an aspect of the present invention, there is provided a semiconductor storage device comprising:

first and second memory cells each having an information-storable first storage area in the vicinity of one end of a channel region as well as an information-storable second storage area in the vicinity of the other end of the channel region, and having a first input/output terminal on one end side of the channel region and a second input/output terminal on the other end side of the channel region;

a first bit line to which the first input/output terminal of the first memory cell is connected;

a second bit line to which the second input/output terminal of the second memory cell is connected;

a common line to which the second input/output terminal of the first memory cell and the first input/output terminal of the second memory cell are connected;

a word line to which control gates of the first memory cell and the second memory cell are connected;

a first bit line driver to an output of which the first bit line is connected;

a second bit line driver to an output of which the second bit line is connected;

a common line driver to an output of which the common line is connected; and

a sense amplifier to inputs of which the first and second bit lines are connected, respectively.

According to another aspect of the present invention, there is provided a semiconductor storage device comprising:

first and second memory cells each having an information-storable first storage area in the vicinity of one end of a channel region as well as an information-storable second storage area in the vicinity of the other end of the channel region, and having a first input/output terminal on one end side of the channel region and a second input/output terminal on the other end side of the channel region;

a first local bit line to which the first input/output terminal of the first memory cell is connected;

a second local bit line to which the second input/output terminal of the second memory cell is connected;

a third local bit line to which the second input/output terminal of the first memory cell and the first input/output terminal of the second memory cell are connected;

first to third switching elements to one-side ends of which the first to third local bit lines are connected, respectively;

a first global bit line to which the other end of the first switching element is connected;

a second global bit line to which the other end of the second switching element is connected;

a common line to which the other end of the third switching element is connected;

a word line to which control gates of the first memory cell and the second memory cell are connected;

a first bit line driver to an output of which the first global bit line is connected;

a second bit line driver to an output of which the second global bit line is connected;

a common line driver to an output of which the common line is connected; and

a sense amplifier to inputs of which the first and second global bit lines are connected, respectively.

In this structure, the first and second memory cells each have the first storage area and the second storage area in the vicinities of both ends of the channel region, and the read operation is fulfilled by utilizing status differences of the two memory cells having the first storage area and the second storage area.

Therefore, according to this structure, information stored in the memory cells can correctly be read out without using any reference voltage or reference cell.

In one embodiment, either one or both of the storage areas of the first memory cell are set to an erase state while either one or both of the storage areas of the second memory cell are set to a write state so that data 0 or data 1 is stored, and, conversely, either one or both of the storage areas of the first memory cell are set to a write state while either one or both of the storage areas of the second memory cell are set to an erase state so that data 1 or data 0 is stored.

In this embodiment, since the read operation is fulfilled by utilizing status differences of the first and second memory cells, information stored in the memory cells can correctly be read out without using any reference voltage or reference cell.

Further, using only one of the storage areas in the vicinities of both ends of the channel region makes it possible to improve endurance characteristics.

In one embodiment, each of the first and second memory cells is a side wall memory.

In the side wall memory, by controlling the voltages of a source region, a drain region and a gate, two storage areas, i.e. two charge retention areas, are controlled in their charge retention state independently of each other, by which information is stored in each of the storage areas.

Thus, one memory cell formed of the side wall memory, having two charge retention areas, i.e. two storage areas, is enabled to effectively enhance the degree of integration of the semiconductor storage device.

In the side wall memory having two storage areas, an electric current involved in reading information stored in one of the storage areas is affected by the charge retention state of the other storage area. Accordingly, the memory cells are characterized by larger variations in current value, as compared with memory cells each having one storage area.

However, in this semiconductor storage device, since a status comparison between the first memory cell and the second memory cell is performed, information stored in the memory cells can be discriminated correctly even if current distributions resulting from currents passed from the first input/output terminal to the second input/output terminal in a plurality of memory cells selected by one word line, and current distributions resulting from currents passed from the second input/output terminal to the first input/output terminal in a plurality of memory cells selected by one word line, have undergone variations, or have shifted with time elapses, or have overlapped with each other.

Electronic equipment of the present invention is characterized by including the semiconductor storage device described above.

Herein, the term “electronic equipment” refers to portable telephones or other personal digital assistants, liquid crystal displays, DVD devices, imaging devices, audio devices, copiers and the like.

According to the present invention, since the electric equipment includes the above-described semiconductor storage device capable of discriminating information with high accuracy by a relatively simple construction, reliability of the electronic equipment can be improved.

According to the semiconductor storage device of the present invention, since the read operation is fulfilled by utilizing status differences of the first and second memory cells, information stored in the memory cells can correctly be read out without using any reference voltage or reference cell.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a view showing a semiconductor storage device according to a first embodiment of the present invention;

FIG. 2 is a view showing a semiconductor storage device in which other memory cells are employed in the first embodiment of the invention;

FIG. 3 is a view showing a semiconductor storage device in which other memory cells are employed in the first embodiment of the invention;

FIG. 4 is a circuit diagram showing an example of a bit line driver;

FIG. 5 is a circuit diagram showing an example of a common line driver;

FIG. 6 is a circuit diagram showing an example of a sense amplifier;

FIG. 7 is a sectional view of a side wall memory;

FIG. 8 is a circuit diagram showing one set of memory cells constituting a 1 bit;

FIG. 9 is a view showing a semiconductor storage device according to a second embodiment of the present invention;

FIG. 10 is a view showing a semiconductor storage device according to a third embodiment of the present invention;

FIG. 11 is a view showing another example of a memory cell;

FIG. 12 is a view showing another example of a memory cell;

FIG. 13 is a view showing another example of a memory cell;

FIG. 14 is a view showing another example of a memory cell;

FIG. 15 is a view showing another example of a memory cell;

FIG. 16 is a block diagram showing a digital camera which is an embodiment of electronic equipment according to the invention;

FIG. 17 is a view showing a relationship between individual operations and voltages applied to the word line, the bit line and the common line;

FIG. 18 is a view showing a relationship between individual operations and voltages applied to the word line, the bit line and the common line;

FIG. 19 is a view showing a relationship between individual operations and voltages applied to the word line, the bit line and the common line;

FIG. 20 is a view showing a relationship between individual operations and voltages applied to the word line, the bit line and the common line;

FIG. 21 is a view showing a relationship between individual operations and voltages applied to the word line, the bit line and the common line;

### DETAILED DESCRIPTION OF THE INVENTION

Hereinbelow, the present invention will be described in detail by embodiments thereof illustrated in the accompanying drawings.

### First Embodiment

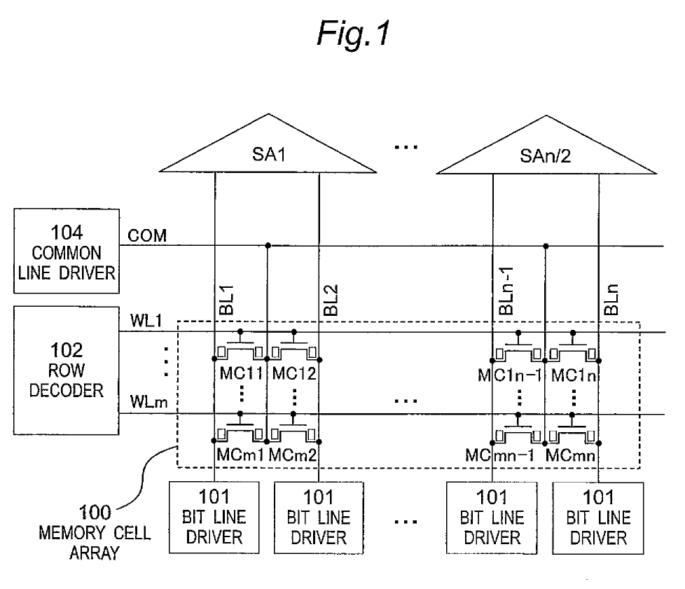

FIG. 1 is a view showing a semiconductor storage device according to a first embodiment of the present invention. This semiconductor storage device includes a memory cell array 100 formed from a multiplicity of nonvolatile memory cells MC11-MCmn arranged in a matrix form. A plurality of word lines WL1-WLm connected to control gates of memory cells arrayed on their corresponding same rows, respectively, are provided so as to extend along the row direction of the memory cell array 100. Further, a common line COM extends so as to be connected to row-directionally adjacent second and first input/output terminals of first and second memory cells MC11 and MC12, MC21 and MC22, . . . , MCm1 and MCm2, . . . , MC1n-1 and MC1n, MC2n-1 and MC2n, . . . , MCmn-1 and MCmn on the basis of each adjacent two-column sets in the memory cell array 100. Also, a plurality of bit lines BL1-BLn as first and second bit lines extend so as to be connected to first and second input/output terminals, opposite to the second and first input/output terminals connected to the common line COM, of the row-directionally adjacent two first and second memory cells MC11 and MC12, MC21 and MC22, . . . , MCm1 and MCm2, . . . , MC1n-1 and MC1n, MC2n-1 and MC2n, . . . , MCmn-1 and MCmn, respectively. The word lines WL1-WLm are connected to a row decoder 102 by which arbitrary word lines are selected. The bit lines BL1-BLn are connected to outputs of bit line drivers 101 as first and second bit line drivers, respectively, and pairs of first and second bit lines BL1 and BL2, . . . BLn-1 and BLn are connected to sense amplifiers SA1-SAn, respectively. The common line COM is connected to a common line driver 104.

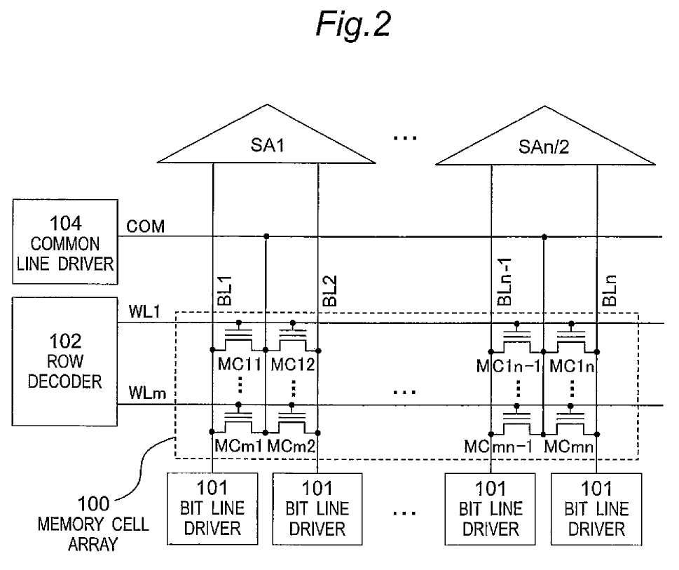

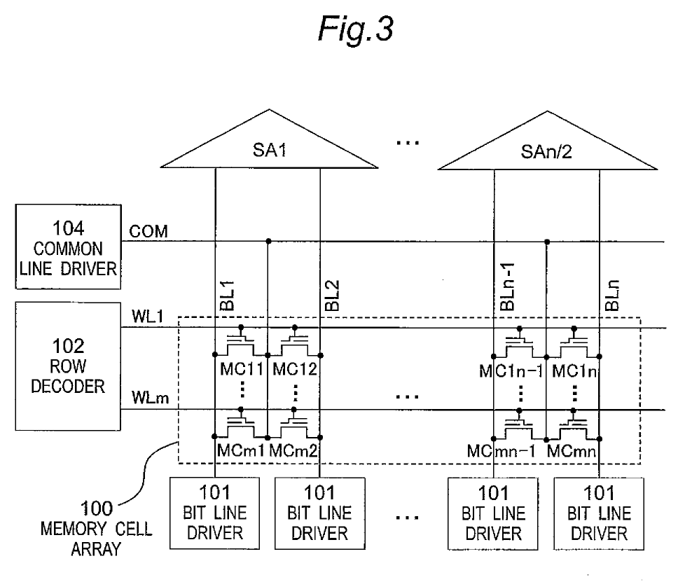

In FIG. 1, the memory cells MC11-MCmn are each a so-called side wall memory having two storage areas, but may also be each a memory cell having only one storage node as a storage area such as shown in FIGS. 2 and 3. The memory cells of FIGS. 2 and 3 each have a floating gate formed of a material typified by polysilicon. The memory cells MC11 and MC12, MC21 and MC22, . . . , MCm1 and MCm2, . . . of FIG. 2, which are so-called flash memory, each have one storage area near the channel region. The memory cells MC11 and MC12, MC21 and MC22, . . . , MCm1 and MCm2, . . . of FIG. 3 each have one storage area near one end of the channel region. The structures of the memory cells of FIGS. 2 and 3 are well known and so their detailed description is omitted.

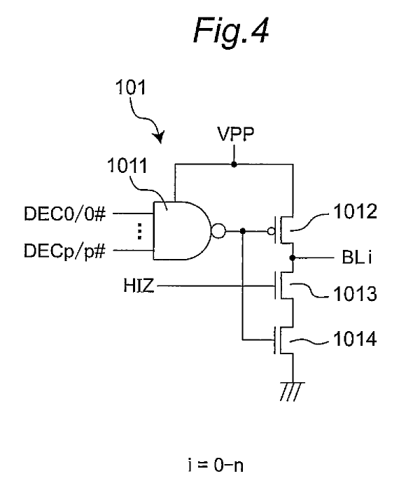

FIG. 4 shows an example of a circuit configuration of the bit line driver 101. This circuit includes a NAND gate 1011, FETs (Field Effect Transistors) 1012, 1013, 1014. In this circuit, selection is made depending on decode signals DEC0-DECp and their respective inverted signals DEC0#-DECp#, so that only from bit line drivers 101 in which the output of the NAND gate 1011 has become a low level (hereinafter, expressed simply as Low), a voltage VPP (e.g., 5 V) is outputted to the bit lines BLi (i=0−n) while outputs of the other bit lines BLi (i=0−n) each become 0 V. However, for read operation, since the bit lines BLi (i=0−n) need to be set to a high impedance state, the output of the NAND gate 1011 and an input signal HIZ to the gate of the N-type FET 1013 both become a high level (hereinafter, expressed as High).

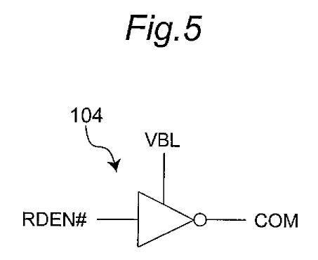

FIG. 5 shows an example of a circuit configuration of the common line driver 104, where the circuit is formed by an inverter. In this circuit, in read operation, a voltage VBL (e.g., 1.2 V) is outputted when an input signal RDEN# goes Low.

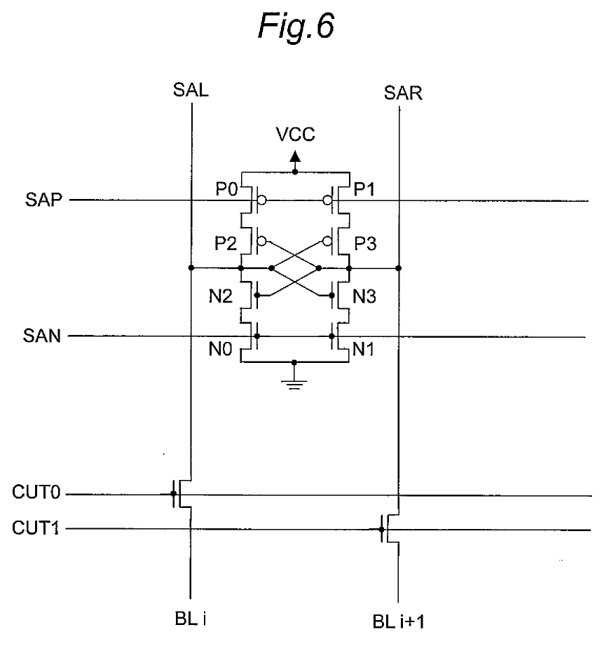

FIG. 6 shows an example of a circuit configuration of a sense amplifier SAi (i=1−n/2), where this circuit includes P-type FETs P0-P3 and N-type FETs N0-N3. In this circuit, for read operation, voltages of the bit lines BLi, BLi+1 are fetched as input voltages, control signals CUT0, CUT1 are set Low to confine the voltages in the sense amplifier lines SAL, SAR, and thereafter a control signal SAP is set to fall from High to Low and a control signal SAN is set to rise from Low to High, by which an amplification operation is performed. The operation goes as it does with a conventional DRAM sense amplifier.

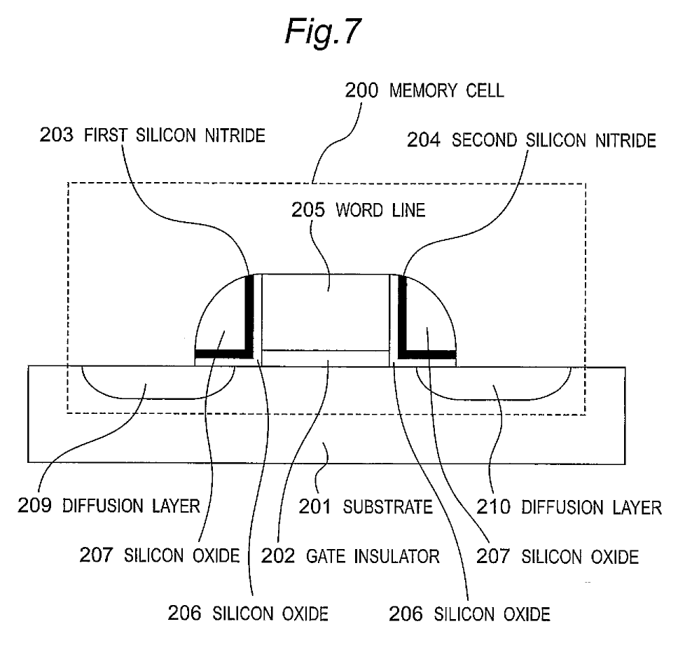

FIG. 7 is a sectional view of a side wall memory 200 used as a memory cell in the first embodiment.

This side wall memory 200 includes first silicon nitride 203 as a first storage area serving as charge retention area (storage node), and second silicon nitride 204 as a second storage area. In the side wall memory 200, 1-bit information of data 0 or data 1 is to be stored therein by writing information into either one of the first silicon nitride 203 and the second silicon nitride 204. On a substrate 201, a word line 205 serving as a gate electrode is formed via gate insulator 202, and first and second silicon nitrides 203, 204 are formed on both sides of the word line 205 via silicon oxides 206. Each of the first and second silicon nitrides 203, 204 has a longitudinal portion extending generally parallel to a side wall of the word line 205, and a lateral portion adjoining a lower end of the longitudinal portion and extending generally parallel to the substrate 201 surface and toward one side farther from the word line 205, as well as a generally L-shaped cross-sectional configuration. Silicon oxides 207, 207 are provided each on one side of the first and second silicon nitrides 203, 204 farther from the word line 205. Thus, with the first and second silicon nitrides 203, 204 sandwiched by the silicon oxide 206 and the silicon oxide 207, the charge injection efficiency in rewrite operation is enhanced, by which a high-speed operation is realized. On the substrate 201 in adjacency to the first and second silicon nitrides 203, 204 are formed diffusion layers 209, 210 as two diffusion areas. More specifically, the diffusion layer 209 is formed so as to overlap with part of the lateral portion of the first silicon nitride 203. Further, the diffusion layer 210 is formed so as to overlap with part of the lateral portion of the second silicon nitride 204. The diffusion layers 209, 210 function as a source region or a drain region, respectively. A channel region is defined between the diffusion layer 209 and the diffusion layer 210.

Next, write, erase and read operations to the memory cells in the first embodiment are explained below.

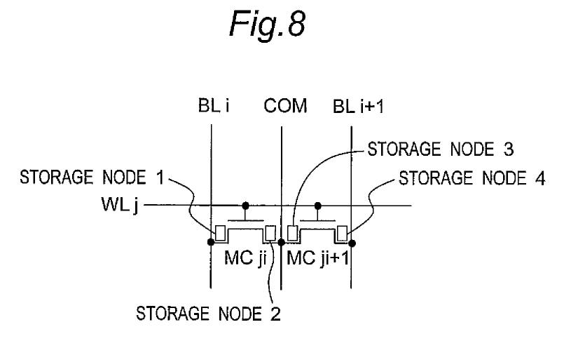

In the present invention, as shown in FIG. 8, 1-bit information is stored by one set of two memory cells. In this case, for example, for data 0, a storage node 1 as a first storage area of a left-side memory cell MCji as a first memory cell is set to an erase state, a storage node 4 as a second storage area of a right-side memory cell MCji+1 as a second memory cell is set to a write state, and storage nodes 2, 3 as second and first storage areas are held in an erase state (or in a virgin state just after manufacture). Further, for example, for data 1, the storage node 1 of the left-side memory cell MCji is set to a write state, the storage node 4 of the right-side memory cell MCji+1 is set to an erase state, and the storage nodes 2, 3 are held in an erase (or a virgin state just after manufacture). In addition, in a case where each memory cell has only one storage node such as shown in FIGS. 2 and 3, for example, for data 0, the storage node of the left-side memory cell MCji is set to an erase state, the storage node of the right-side memory cell MCji+1 is set to a write state, and for data 1, vice versa.

It is noted that the definitions for data 0 and data 1 may be reversed to those shown above. Further, although the method may be that data are written into both storage nodes 1, 2 as the first and second storage areas, or both storage nodes 3, 4 as the first and second storage areas, concurrently, yet a method in which data is written into only one of the storage nodes (storage nodes 1 and 4 in the above example) is superior in terms of endurance characteristics.

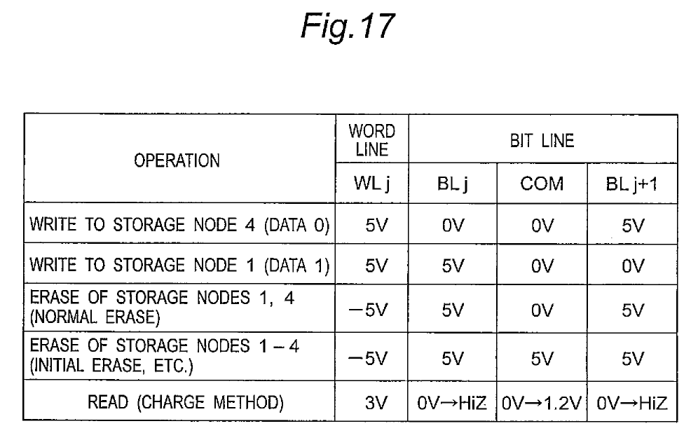

For performing such write operation, for example, such voltages as shown in FIG. 17 are applied to the word line WLj, the bit lines BLi, BLi+1 and the common line COM, respectively. That is, in order to set data 0, such a voltage as shown in the first field row of FIG. 17 is applied to do write into the storage node 4. Also, in order to set data 1, such a voltage as shown in the second field row of FIG. 17 is applied to do write into the storage node 1.

For fulfilling an ordinary erase, such a voltage as shown in the third field row of FIG. 17 may be applied. Also, for an initial erase immediately after manufacture to erase all the storage nodes, such a voltage as shown in the fourth field row of FIG. 17 is applied. In this case, the voltage VBL of FIG. 5 needs to be set equal in value to the voltage VPP of FIG. 4.

Further, for read operation, as shown in the fifth field row of FIG. 17, the bit line BLi, the bit line BLi+1 and the common line COM are first set all to 0 V. Thereafter, the bit line BLi and the bit line BLi+1 are set to a high impedance state (HiZ), and a voltage of 3 V is applied to the word line WLj, and a voltage of 1.2 V as an example is applied to the common line COM, so that the bit lines BLi, BLi+1 are charged. At a proper timing, the voltages of the bit lines are fetched to the sense amplifier SAi, by which an amplification operation is performed. This goes as described in conjunction with FIG. 6.

As shown above, read operation is performed by using the voltages of the bit lines BLi, BLi+1, i.e., status differences of the first and second memory cells MCji, MCji+1. Thus, information stored in the first and second memory cells MCji, MCji+1 can correctly be read out without using any reference voltage or reference cell.

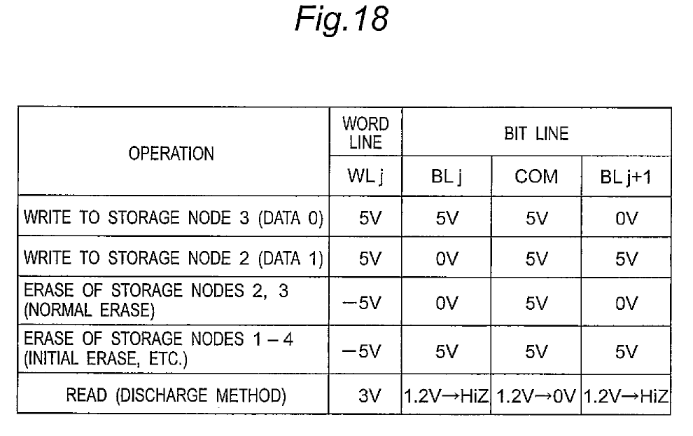

The above description has been made on the method for charging the bit lines BLi, BLi+1 in terms of the read operation. Conversely, the method may be that the bit lines BLi, BLi+1 are discharged from a voltage of 1.2 V as an example. In this case, however, read characteristics become better in the side wall memory when not the storage nodes 1, 4 but the storage nodes 2, 3 are used, and so the voltages to be applied should be changed as shown in FIG. 18.

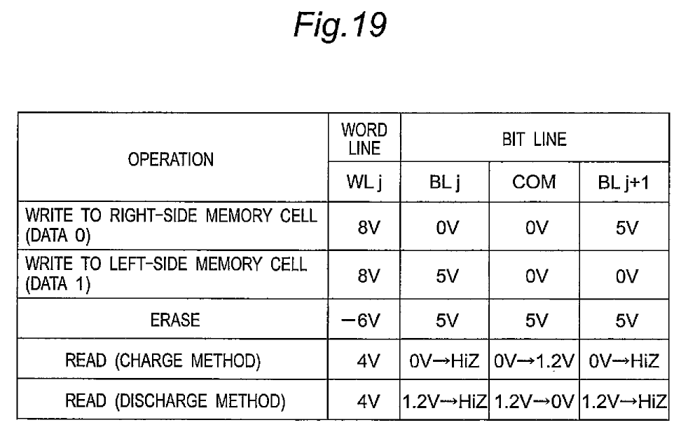

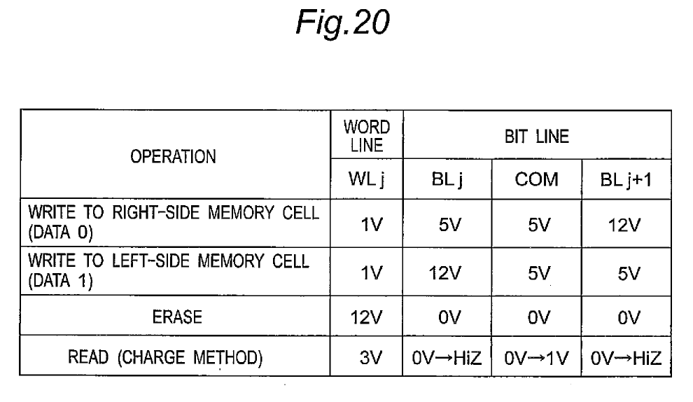

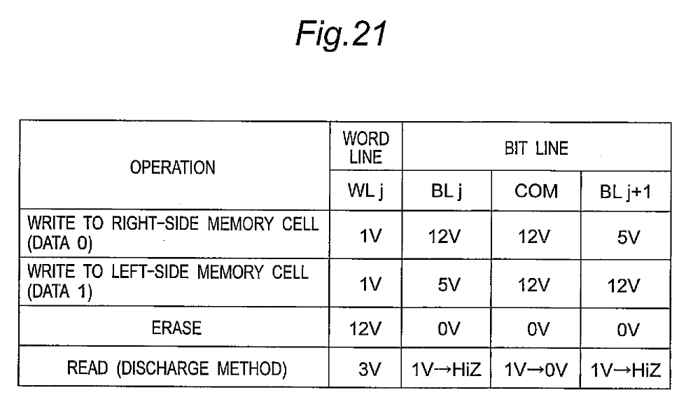

When the memory cells of FIG. 2 are used, such voltages as shown in FIG. 19 are applied. With the use of the memory cells of FIG. 3, it is recommendable that such voltages as shown in FIG. 20 are applied if the read operation is done by the charging method, and such voltages as shown in FIG. 21 are applied with the memory cells all inverted in direction between right and left if the read operation is done by the discharging method.

### Second Embodiment

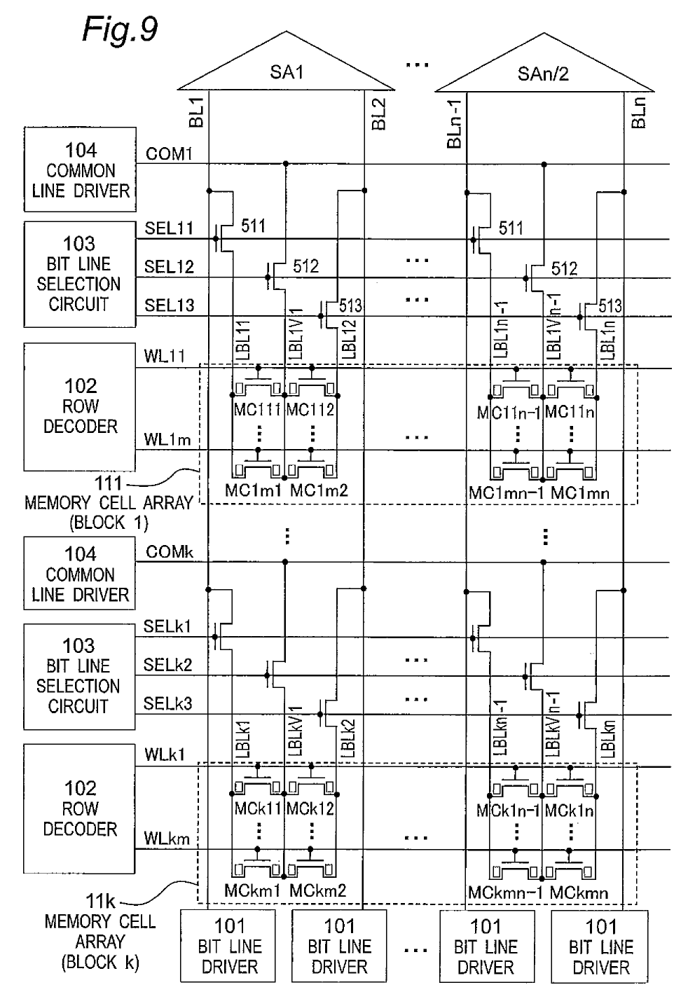

FIG. 9 is a view showing a semiconductor storage device according to a second embodiment of the invention. In FIG. 9, the same components as those of FIG. 1 are designated by the same reference numerals as those of FIG. 1 and their description is omitted.

This semiconductor storage device includes a plurality of memory cell arrays 111-11k formed from a multiplicity of nonvolatile memory cells MC111-MCkmn arranged in a matrix form. It is noted here that k, m and n are natural numbers. Usually, each of the memory cell arrays 111-11k are referred to as a block. In this case, k blocks are shown. Since block selection is required for individual operations, bit line selection circuits 103 are provided. For example, a memory cell array (block 1) 111 can be selected by setting output signals SEL11, SEL12, SEL13 to High, turning on FETs 511, 513, 512 as an example of first, second and third switching elements, and by setting the other output signals SEL21, SEL22, SEL23-SELk1, SELk2, SELk3 to Low. The output signals SEL11, SEL12, SEL13, although given as independent signals in this case, may also be unified into one signal. The rest of the constitution is similar to that of the first embodiment.

Referring to FIG. 9, LBL11, . . . , LBL1n-1, . . . , LBLk1, . . . , LBLkn-1 denote first local bit lines, LBL12, . . . , LBL1n, . . . , LBLk2, . . . , LBLkn denote second local bit lines, and LBL1V1, . . . , LBL1Vn-1, . . . , LBLkV1, . . . , LBLkVn-1 denote third local bit lines. One-side ends of the first to third local bit lines are connected to one-side ends of the FETs 511, 513, 512 as the first to third switching elements, respectively.

Also, a first global bit line BL1 is connected between the FETs 511 as the first switching elements and inputs of the sense amplifiers SA-SAn/2, respectively. A second global bit line BL2 is connected between the FETs 513 as the second switching elements and inputs of the sense amplifiers SA-SAn/2, respectively. Further, common lines COM1-COMk are connected between the FETs 512 as the third switching elements and the common line drivers 104, respectively.

According to this second embodiment, the first to third local bit lines LBL11, . . . , LBL1n-1, . . . , LBLk1, . . . , LBLkn-1; LBL12, . . . , LBL1n, . . . , LBLk2, . . . , LBLkn; LBL1V1, . . . , LBL1Vn-1, . . . , LBLkV1, . . . , LBLkVn-1 are connected to one-side ends of the FETs 511, 513, 512 as the first to third switching elements, respectively, and moreover the first global bit lines BL1 . . . BL1n-1, to which the other-side ends of the FETs 511 are connected, and the second global bit lines BL2 . . . BLn, to which the other-side ends of the FETs 513 are connected, are connected to inputs of the sense amplifiers SA-SAN/2, respectively. Therefore, with one sense amplifier, a plurality of memory cell sets in the column direction, i.e., in the bit line direction are read out, and therefore the number of memory cells that can be read out by one sense amplifier can be increased without impairing the reading accuracy.

### Third Embodiment

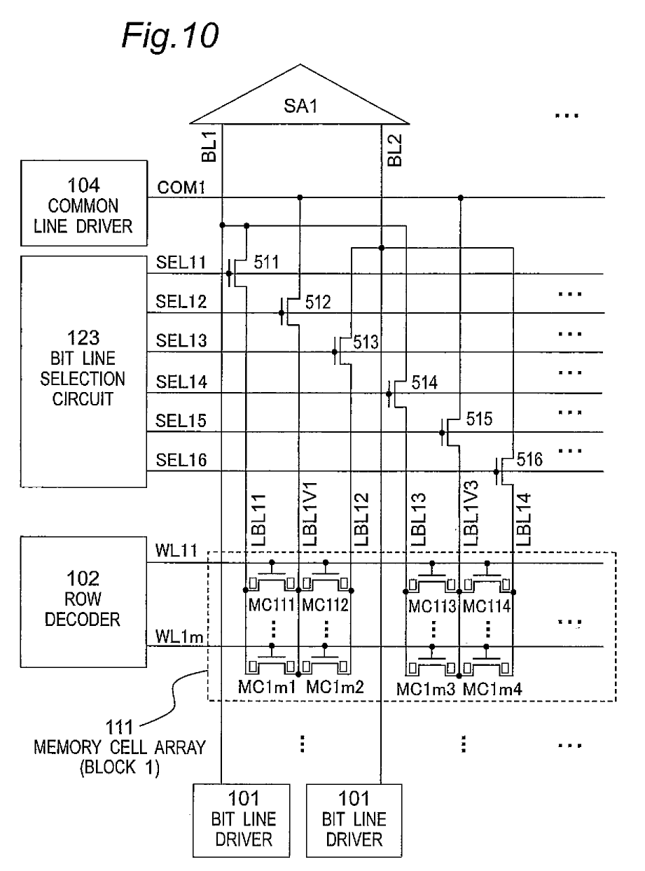

FIG. 10 is a view showing a semiconductor storage device according to a third embodiment of the invention. In FIG. 10, the same components as those of FIGS. 1 and 9 are designated by the same reference numerals as those of FIGS. 1 and 9 and their description is omitted.

Although the memory cell array (block 1) 111 alone is shown in this case, yet individual blocks are selected by bit line selection circuits 123 as in the case of the second embodiment.

However, in this case, since the bit line drivers 101 and the sense amplifier SA1 are shared by the memory cells MC111-MC1m2 and the memory cells MC113-MC1m4, the number of bit-line selection signal lines is increased to a double, i.e. six, for selection of the memory cells. For selection of the memory cells MC111-MC1m2, the bit-line selection signals SEL11, SEL12, SEL13 are set to High, and the bit-line selection signals SEL14, SEL15, SEL16 are set to Low. Also, for selection of the memory cells MC113-MC1m4, the bit-line selection signals SEL11, SEL12, SEL13 are set to Low, and the bit-line selection signals SEL14, SEL15, SEL16 are set to High. Although the bit-line selection signals SEL11-SEL16 are given as independent signals in this case, yet the bit-line selection signals SEL11-SEL13 may be unified to one signal, and the bit-line selection signals SEL14-SEL16 may be unified to one signal. The rest of the constitution is similar to that of the second embodiment.

In addition, transistors 511-516, to the gates of which the bit-line selection signals SEL11-SELk3 of FIG. 9 used in the second embodiment or the bit-line selection signals SEL11-SEL16 of FIG. 10 used in the third embodiment are to be inputted, are shown by N-channel transistors. However, paired sets of P-channel transistor and N-channel transistor are preferably used in order to reduce the voltages to be applied to the gates (High level for the bit-line selection signals SEL11-SELk3 and the bit-line selection signals SEL11-SEL16, . . . ). In addition, with the use of the voltage application method shown in FIG. 17, which is characterized in that only voltages not higher than VBL (e.g., 1.2V) are applied to the common line COM except for the initial erase operation, if the power source voltage is about VBL+Vth (threshold of N-channel transistors) (e.g., 1.8 V) or higher, the transistors to the gates of which the bit-line selection signals SEL12, SEL22, . . . , SELk2 of FIG. 9, the bit-line selection signals SEL12, SEL15, . . . of FIG. 10 are to be inputted can be given by N-channel transistors alone, allowing an area reduction to be achieved.

According to this third embodiment, the first to third local bit lines LBL11, LBL13; LBL12, LBL4; LBL1V1, LBL13 are connected to one-side ends of the FETs 511, 513, 512 as the first to third switching elements, respectively, and moreover the first global bit line BL1, to which the other-side ends of the FETs 511 are connected, and the second global bit line BL2, to which the other-side ends of the FETs 513 are connected, are connected to inputs of the sense amplifiers, respectively. Therefore, with one sense amplifier SA1, information that can be read out of a plurality of memory cell sets in the row direction, i.e., in the word line direction, and therefore the number of memory cells that can be read out by one sense amplifier SA1, can be increased without impairing the reading accuracy.

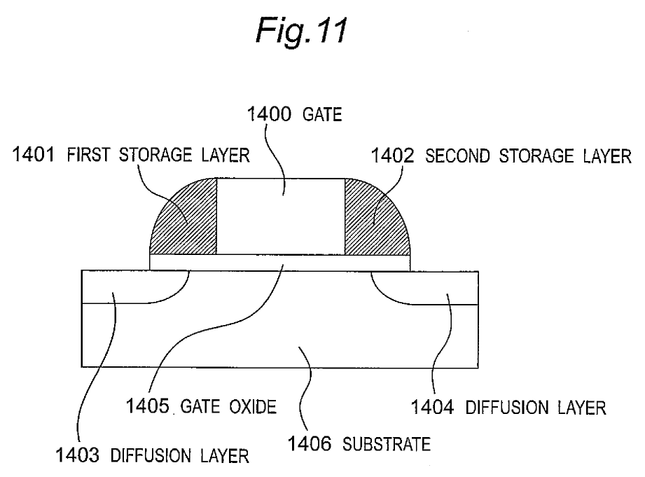

In addition, although the side wall memory whose cross-sectional structure is shown in FIG. 7 is employed in the semiconductor storage devices of the first to third embodiments, yet the memory cells shown in FIGS. 2 and 3 may also be used as described in the first embodiment. Further, the memory cells whose cross-sectional views are shown in FIGS. 11 to 15, which are of the type that two storage nodes as storage areas are possessed, may also be employed. Several examples of memory cells that can be used in the semiconductor storage devices of the present invention are explained below with reference to FIGS. 11 to 15.

Memory cells included in the present invention may also have a structure shown in FIG. 11. That is, oxide 1405 and gate 1400 are stacked on a substrate 1406 one by one, and a first storage layer 1401 as a first storage area and a second storage layer 1402 as a second storage area are stacked generally left-and-right symmetrically on the oxide 1405 and on both sides of the gate 1400. Further, a first diffusion layer 1403 is formed between the substrate 1406 and the oxide 1405 so as to partly overlap with the first storage layer 1401 in the stacking direction, and a second diffusion layer 1404 is formed so as to partly overlap with the second storage layer 1402 in the stacking direction and not to intersect the first diffusion layer 1403.

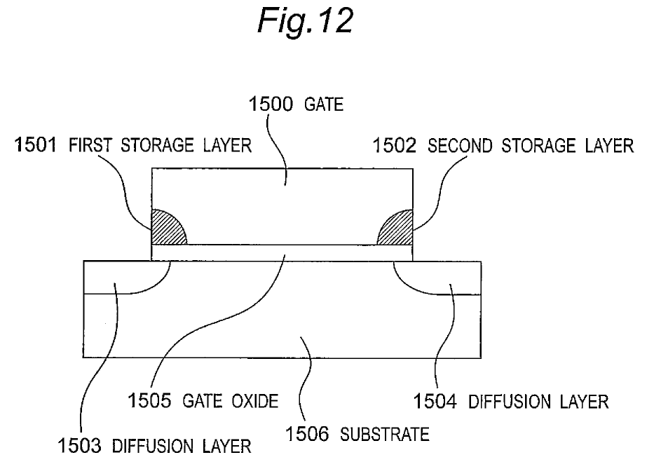

Also, memory cells included in the present invention may also have a structure shown in FIG. 12. That is, oxide 1505 and gate 1500 are stacked on a substrate 1506 one by one, and a first storage layer 1501 as a first storage area having a quadrant-shaped cross section and a second storage layer 1502 as a second storage area having a quadrant-shaped cross section are formed left-and-right symmetrically at two corners of the gate 1500 on one side closer to the oxide 1505. Further, a first diffusion layer 1503 is formed between the substrate 1506 and the oxide 1505 so as to partly overlap with the first storage layer 1501 in the stacking direction, and a second diffusion layer 1504 is formed so as to partly overlap with the second storage layer 1502 in the stacking direction and not to intersect the first diffusion layer 1503.

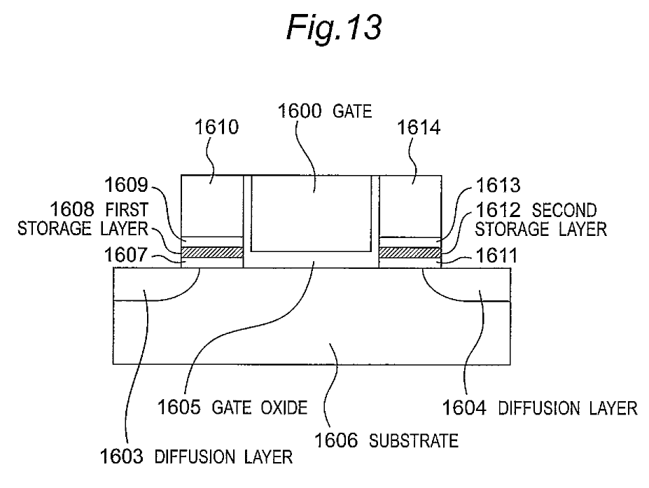

Also, memory cells included in the present invention may also have a structure shown in FIG. 13. That is, gate oxide 1605 having a generally recess-shaped cross section is formed on a substrate 1606, and gate 1600 is formed at the recessed portion of the oxide 1605. Further, oxide 1607, a first storage layer 1608 as a first storage area, oxide 1609 and gate 1610 are stacked on the substrate 1606 and one side of the oxide 1605, while oxide 1611, a second storage layer 1612 as a second storage area, oxide 1613 and gate 1614 are stacked on the substrate 1606 and on the other side of the oxide 1605. Furthermore, a first diffusion layer 1603 is formed between the substrate 1606 and the oxide 1607 so as to partly overlap with the first storage layer 1608 in the stacking direction, and a second diffusion layer 1604 is formed between the substrate 1606 and the oxide 1611 so as to partly overlap with the second storage layer 1612 in the stacking direction and not to intersect the first diffusion layer 1603.

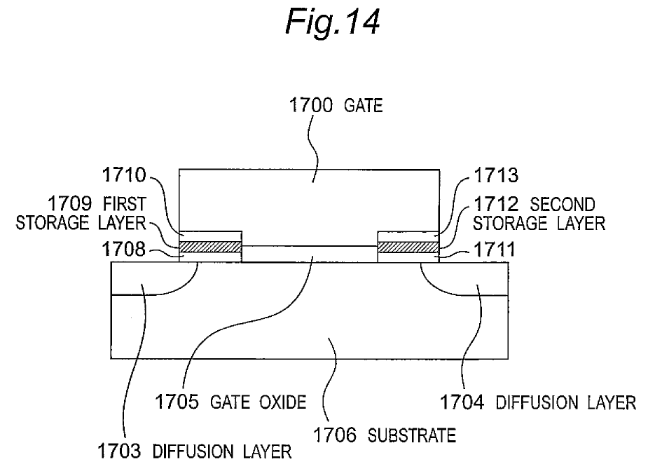

Furthermore, memory cells included in the present invention may also have a structure shown in FIG. 14. That is, oxide 1705 is formed on a substrate 1706, and a gate 1700 is formed on the oxide 1705 so a convex side of its convex cross-sectional shape as to be in contact with the overall top surface of the oxide 1705. Further, oxide 1708, a first storage layer 1709 as a first storage area and oxide 1710 are formed one by one on one side of the oxide 1705 and between the substrate 1706 and the gate 1700, while oxide 1711, a second storage layer 1712 as a second storage area and oxide 1713 are formed one by one on the other side of the oxide 1705 and between the substrate 1706 and the gate 1700. Furthermore, a first diffusion layer 1703 is formed between the substrate 1706 and the oxide 1708 so as to partly overlap with the first storage layer 1709 in the stacking direction, and a second diffusion layer 1704 is formed between the substrate 1706 and the oxide 1711 so as to partly overlap with the second storage layer 1712 in the stacking direction and not to intersect the first diffusion layer 1703.

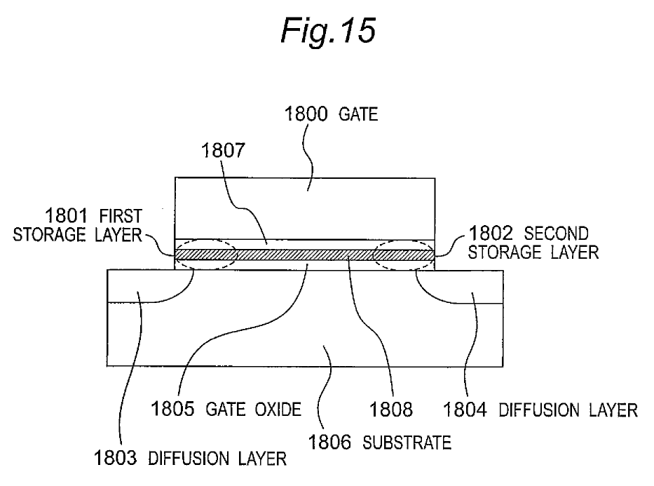

Furthermore, memory cells included in the present invention may also have a structure shown in FIG. 15. That is, gate oxide 1805, silicon nitride 1807, oxide 1808 and gate 1800 are formed on a substrate 1806 one by one. Further, a first diffusion layer 1803 is formed between the substrate 1806 and the gate oxide 1805 so as to partly overlap with the silicon nitride 1807 in the stacking direction, and a second diffusion layer 1804 is formed between the substrate 1806 and the gate oxide 1805 so as to partly overlap with the silicon nitride 1807 in the stacking direction and not to intersect the first diffusion layer 1803. In addition, in the structure shown in FIG. 15, one side in a lateral direction of a sandwich structure composed of the gate oxide 1805, the silicon nitride 1807 and the oxide 1808 is used as a first storage part 1801 serving as a first storage area, while the other side in the lateral direction of the sandwich structure is used as a second storage part 1802 serving as a second storage area.

### Fourth Embodiment

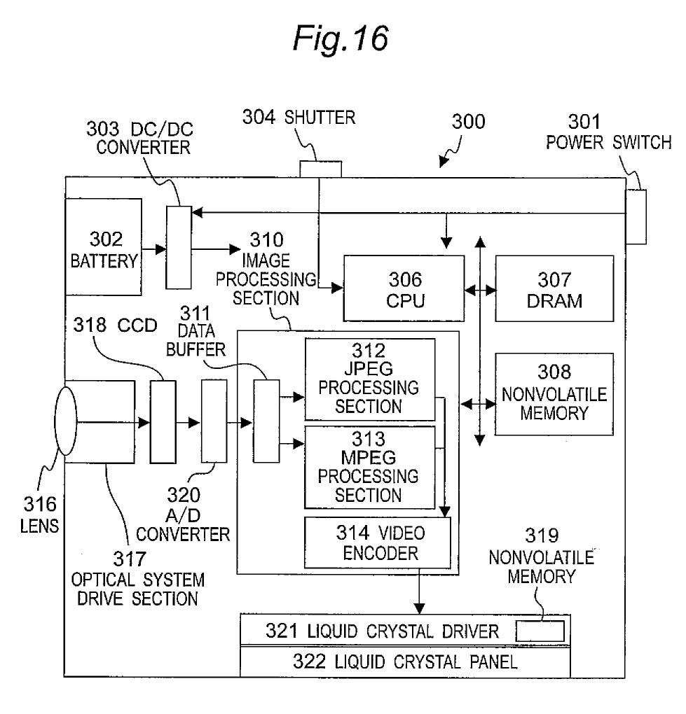

FIG. 16 is a block diagram showing a digital camera 300 which is an embodiment of electronic equipment according to the invention.

This digital camera 300 includes nonvolatile memories 308, 319 which are semiconductor storage devices according to any one of the first to third embodiments of the invention. The nonvolatile memory 308 is used for storage of shot images, while the nonvolatile memory 319 is used for storage of variation correction values of a liquid crystal panel 322 in a liquid crystal driver 321.

In this digital camera 300, when a power switch 301 is turned on by an operator, electric power fed from a battery 302 is transformed into a specified voltage by a DC/DC converter 303, and fed to individual component parts. Light inputted from a lens 316 driven by an optical system drive section 317 is converted into an electric current by a CCD 318, further converted into a digital signal by an A/D converter 320, and inputted to a data buffer 311 of an image processing section 310. The signal inputted to the data buffer 311 is processed in motion picture by an MPEG processing section 313, transformed into a video signal through a video encoder 314, thus being displayed on the liquid crystal panel 322 by the liquid crystal driver 321. In this case, the liquid crystal driver 321 corrects variations of the liquid crystal panel 322 (e.g., variations in hue that differ among liquid crystal panels) by using data of the built-in nonvolatile memory 319. When a shutter 304 is depressed by an operator, information stored in the data buffer 311 is processed as a still picture through a JPEG processing section 312, and recorded in the nonvolatile memory 308, which is a flush memory. In this flash memory 308, also recorded are system programs in addition to shot image information. A DRAM 307 is used for temporary storage of data that are generated in various types of processes by a CPU 306 and the image processing section 310.

The nonvolatile memories 308, 319 of the digital camera 300 need to have high reliability for long-term data retention. In this case, even if the gap that separates distributions of cell current values between data 0 and data 1 becomes extremely narrow or overlapped with each other, the nonvolatile memories 308, 319 can read out information stored in the memory cells by comparing current values in the left-and-right two directions with each other. Thus, the digital camera 300 including the nonvolatile memories 308, 319 is enabled to achieve cost reduction, size reduction and higher reliability.

Although the semiconductor storage device of the invention is mounted on a digital camera in the above embodiment, yet the semiconductor storage device of the invention may preferably be mounted on portable telephones. Flash memories to be used in portable telephones, in which recording of communication protocols in addition to image data is involved, need to have high-degree reliability. Accordingly, when the semiconductor storage device of the invention is mounted on a portable telephone, the quality of the portable telephone can be improved to a great extent.

Furthermore, the semiconductor storage device of the invention, needless to say, may be mounted also on electronic equipment other than digital cameras and portable telephones, such as digital voice recorders, DVD (Digital Versatile Discs) devices, color tone adjustment circuits for liquid crystal displays, music recording/reproducing devices, imaging devices, audio devices and copiers.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A semiconductor storage device comprising:
first and second memory cells each having an information-storable storage area in the vicinity of a channel region or in the vicinity of one end of the channel region, and having a first input/output terminal on one end side of the channel region and a second input/output terminal on the other end side of the channel region;
a first bit line to which the first input/output terminal of the first memory cell is connected;
a second bit line to which the second input/output terminal of the second memory cell is connected;
a common line to which the second input/output terminal of the first memory cell and the first input/output terminal of the second memory cell are connected;
a word line to which control gates of the first memory cell and the second memory cell are connected;
a first bit line driver to an output of which the first bit line is connected;
a second bit line driver to an output of which the second bit line is connected;
a common line driver to an output of which the common line is connected; and
a sense amplifier to inputs of which the first and second bit lines are connected, respectively.

2. The semiconductor storage device as claimed in claim 1, wherein
one set of the first memory cell and the second memory cell, and another set of the first memory cell and the second memory cell adjacent to the one set, share one sense amplifier.

3. The semiconductor storage device as claimed in claim 1, wherein
the storage area of the first memory cell is set to an erase state while the storage area of the second memory cell is set to a write state so that data 0 or data 1 is stored, and, conversely, the storage area of the first memory cell is set to a write state while the storage area of the second memory cell is set to an erase state so that data 1 or data 0 is stored.

4. A semiconductor storage device comprising:
first and second memory cells each having an information-storable storage area in the vicinity of a channel region or in the vicinity of one end of the channel region, and having a first input/output terminal on one end side of the channel region and a second input/output terminal on the other end side of the channel region;
a first local bit line to which the first input/output terminal of the first memory cell is connected;
a second local bit line to which the second input/output terminal of the second memory cell is connected;
a third local bit line to which the second input/output terminal of the first memory cell and the first input/output terminal of the second memory cell are connected;
first to third switching elements to one-side ends of which the first to third local bit lines are connected, respectively;
a first global bit line to which the other end of the first switching element is connected;
a second global bit line to which the other end of the second switching element is connected;
a common line to which the other end of the third switching element is connected;
a word line to which control gates of the first memory cell and the second memory cell are connected;
a first bit line driver to an output of which the first global bit line is connected;
a second bit line driver to an output of which the second global bit line is connected;
a common line driver to an output of which the common line is connected; and
a sense amplifier to inputs of which the first and second global bit lines are connected, respectively.

5. The semiconductor storage device as claimed in claim 4, wherein
one set of the first memory cell and the second memory cell, and another set of the first memory cell and the second memory cell adjacent to the one set, share one sense amplifier.

6. The semiconductor storage device as claimed in claim 4, wherein
the storage area of the first memory cell is set to an erase state while the storage area of the second memory cell is set to a write state so that data 0 or data 1 is stored, and, conversely, the storage area of the first memory cell is set to a write state while the storage area of the second memory cell is set to an erase state so that data 1 or data 0 is stored.

7. A semiconductor storage device comprising:
first and second memory cells each having an information-storable first storage area in the vicinity of one end of a channel region as well as an information-storable second storage area in the vicinity of the other end of the channel region, and having a first input/output terminal on one end side of the channel region and a second input/output terminal on the other end side of the channel region;
a first bit line to which the first input/output terminal of the first memory cell is connected;
a second bit line to which the second input/output terminal of the second memory cell is connected;
a common line to which the second input/output terminal of the first memory cell and the first input/output terminal of the second memory cell are connected;
a word line to which control gates of the first memory cell and the second memory cell are connected;
a first bit line driver to an output of which the first bit line is connected;
a second bit line driver to an output of which the second bit line is connected;
a common line driver to an output of which the common line is connected; and
a sense amplifier to inputs of which the first and second bit lines are connected, respectively.

8. The semiconductor storage device as claimed in claim 7, wherein
one set of the first memory cell and the second memory cell, and another set of the first memory cell and the second memory cell adjacent to the one set, share one sense amplifier.

9. The semiconductor storage device as claimed in claim 7, wherein
either one or both of the storage areas of the first memory cell are set to an erase state while either one or both of the storage areas of the second memory cell are set to a write state so that data 0 or data 1 is stored, and, conversely, either one or both of the storage areas of the first memory cell are set to a write state while either one or both of the storage areas of the second memory cell are set to an erase state so that data 1 or data 0 is stored.

10. The semiconductor storage device as claimed in claim 7, wherein
each of the first and second memory cells is a side wall memory.

11. A semiconductor storage device comprising:
first and second memory cells each having an information-storable first storage area in the vicinity of one end of a channel region as well as an information-storable second storage area in the vicinity of the other end of the channel region, and having a first input/output terminal on one end side of the channel region and a second input/output terminal on the other end side of the channel region;
a first local bit line to which the first input/output terminal of the first memory cell is connected;
a second local bit line to which the second input/output terminal of the second memory cell is connected;
a third local bit line to which the second input/output terminal of the first memory cell and the first input/output terminal of the second memory cell are connected;
first to third switching elements to one-side ends of which the first to third local bit lines are connected, respectively;
a first global bit line to which the other end of the first switching element is connected;
a second global bit line to which the other end of the second switching element is connected;
a common line to which the other end of the third switching element is connected;
a word line to which control gates of the first memory cell and the second memory cell are connected;
a first bit line driver to an output of which the first global bit line is connected;
a second bit line driver to an output of which the second global bit line is connected;
a common line driver to an output of which the common line is connected; and
a sense amplifier to inputs of which the first and second global bit lines are connected, respectively.

12. The semiconductor storage device as claimed in claim 11, wherein
one set of the first memory cell and the second memory cell, and another set of the first memory cell and the second memory cell adjacent to the one set, share one sense amplifier.

13. The semiconductor storage device as claimed in claim 11, wherein
either one or both of the storage areas of the first memory cell are set to an erase state while either one or both of the storage areas of the second memory cell are set to a write state so that data 0 or data 1 is stored, and, conversely, either one or both of the storage areas of the first memory cell are set to a write state while either one or both of the storage areas of the second memory cell are set to an erase state so that data 1 or data 0 is stored.

14. The semiconductor storage device as claimed in claim 11, wherein
each of the first and second memory cells is a side wall memory.

15. Electronic equipment including the semiconductor storage device as defined in claim 1.

16. Electronic equipment including the semiconductor storage device as defined in claim 4.

17. Electronic equipment including the semiconductor storage device as defined in claim 7.

18. Electronic equipment including the semiconductor storage device as defined in claim 11.
